(19) United States
(12) Patent Application Publication
(10) Pub. No.: US 2026/0096022 A1
(43) Pub. Date: Apr. 2, 2026

(54) PACKAGE STRUCTURE

(71) Applicant: Advanced Semiconductor Engineering, Inc., Kaohsiung (TW)

(72) Inventor: Wen Hao TSAI, Kaohsiung (TW)

(73) Assignee: Advanced Semiconductor Engineering, Inc., Kaohsiung (TW)

(21) Appl. No.: 18/900,586

(22) Filed: Sep. 27, 2024

(51) Int. Cl. H05K 1/11; H05K 1/02; H05K 1/18

(52) U.S. Cl. CPC H05K 1/111; H05K 1/0271; H05K 1/181; H05K 2201/09381; H05K 2201/09427

(57) ABSTRACT

A package structure and a method of manufacturing a package structure are provided. The package structure includes a first carrier, a second carrier, and a first component. The first carrier includes a first pad and a second pad disposed at a first surface of the first carrier. The second carrier is disposed above the first carrier. The first component connects the first carrier to the second carrier, and includes a first terminal connected to the first pad and a second terminal connected to the second pad. A first distance between the first pad and the second pad is substantially equal to or greater than a second distance between the first terminal and the second terminal.

### BACKGROUND

### 1. Field of the Disclosure

The present disclosure relates to a package structure and a method of manufacturing a package structure.

### 2. Description of the Related Art

A package structure may include a component attached to a printed circuit board and a molding compound covering the component. However, after the attachment process and thermal treatment, cracks may develop at the boundary between the molding compound and the component.

### SUMMARY

In some embodiments, a package structure includes a first carrier, a second carrier, and a first component. The first carrier includes a first pad and a second pad disposed at a first surface of the first carrier. The second carrier is disposed above the first carrier. The first component connects the first carrier to the second carrier, and includes a first terminal connected to the first pad and a second terminal connected to the second pad. A first distance between the first pad and the second pad is substantially equal to or greater than a second distance between the first terminal and the second terminal.

In some embodiments, a package structure includes a first carrier, a second carrier, and a first component. The second carrier is disposed above the first carrier. The first component is disposed between the first carrier and the second carrier. The first component has a first surface facing the first carrier and a second surface acing the second carrier. A first distance between the first surface and the first carrier is greater than a second distance between the second surface and the second carrier.

In some embodiments, a package structure includes a first carrier and a component. The first carrier includes a first pad. The component is disposed over the first carrier, and includes a first terminal. In a top view, a coverage of the first terminal to the first pad is smaller or equal to about 70%.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of a package structure according to some embodiments of the present disclosure.

FIG. 2 is an enlarged cross-sectional view of a box B1 in FIG. 1.

FIG. 2A is an enlarged cross-sectional view of a box B11 in FIG. 2.

FIG. 2B is an enlarged cross-sectional view of a box B12 in FIG. 2.

FIG. 3 is another enlarged cross-sectional view of a box B1 in FIG. 1.

FIG. 4 is an enlarged cross-sectional view of a box B1 in FIG. 1 in a viewing direction perpendicular to the viewing direction of FIG. 2.

FIG. 5 is an enlarged top view of a box B1 in FIG. 1.

FIG. 6A is a Scanning Electron Microscope (SEM) image of a portion of a package structure according to some embodiments of the present disclosure.

FIG. 6B is an SEM image of a portion of a package structure according to some embodiments of the present disclosure.

FIG. 7 is a cross-sectional view of a package structure according to some embodiments of the present disclosure.

FIGS. 8A, 8B, 8C, 8D, 8E, 8F, and 8G illustrate one or more stages of an example of a method for manufacturing a package structure according to some embodiments of the present disclosure.

FIG. 9 is a cross-sectional view of a package structure according to some embodiments of the present disclosure.

FIG. 10 is an enlarged cross-sectional view of a box B2 in FIG. 9.

FIG. 11 is an SEM image of a portion of a package structure according to some embodiments of the present disclosure.

FIG. 12 is a cross-sectional view of an intermediate structure during the manufacturing of a package structure according to some embodiments of the present disclosure.

FIG. 13 is a cross-sectional view of a package structure according to some embodiments of the present disclosure.

FIG. 14 is an enlarged cross-sectional view of a box B3 in FIG. 13.

FIG. 15 is an SEM image of a portion of a package structure according to some embodiments of the present disclosure.

FIG. 16 is an enlarged cross-sectional view of a box B5 in FIG. 15.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The present disclosure relates to the modification of the locations of pads on a carrier (e.g., printed circuit board). The pads connected to the same component through a solder are spaced apart in a distance substantially equal to or more than a distance between the terminals of said component. The profile of the encapsulating layer between said component and the pads can be shaped to reduce the localized stress at the boundary between the encapsulating layer and said component (or between the encapsulating layer and the solder). The risk of delamination can be reduced. In some embodiments, the distance between the pads may be designed to be shorter than the terminals, but larger than a baseline condition, to reduce the localized stress at the boundary between the encapsulating layer and said component (or between the encapsulating layer and the solder).

After the thermal treatment, an encapsulating layer (e.g., molding compound) has or defines a relatively large angle at the boundary between the component and the solder. The relatively large angle may indicate that the encapsulating layer has a relatively short protrusion at the boundary between the component and the solder. The localized stress at said boundary and the risk of delamination between the component and the encapsulating layer are reduced.

The present disclosure relates to a 3D stacking structure including upper and lower carriers connected with each other through one or more components (e.g., passive components). The one or more components may be mounted to the upper and the lower carriers via solders under surface mount technology (SMT). The solders undergo a thermal treatment (or reflow, curing) and then exhibits a necking profile. Each of the solders is disposed on upper, lateral, and lower surfaces of a respective one of the one or more components. The width of the solders tapers from the upper side toward the middle side and from the lower side toward the middle side. That said, the width of the solders has the smallest value at the lateral surface of the components. In some embodiments, the components are densely arranged (i.e., the spacing therebetween is relatively small), the necking profile with a shorter width at its middle side can prevent bridges among the solders.

The one or more components are mounted to the upper carrier prior to being mounted to the lower carrier. The upper carrier with the one or more components may exhibit warpage (e.g., a smiling profile). During the mounting process of the lower carrier, the amount of solders is relatively large (compared to those for the upper carrier) to compensate for the warpage of the upper carrier. Thus, after thermal treatment, the amount of the solders between the one or more components and the lower carrier is greater than that between the one or more components and the upper carrier. The one or more components are closer to the upper carrier than to the lower carrier.

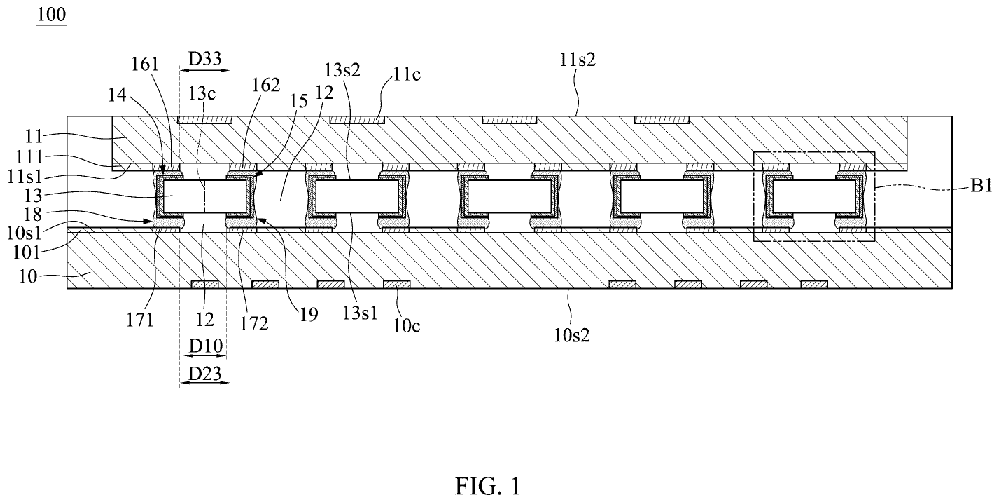

FIG. 1 is a cross-sectional view of a package structure 100 according to some embodiments of the present disclosure. The package structure 100 may include a carrier (or a first carrier, a lower carrier, a lower circuit structure) 10, a carrier (or a second carrier, an upper carrier, an upper circuit structure) 11, an encapsulating layer 12, and a component 13.

The carrier 10 is disposed under the component 13. The carrier 10 is disposed below the carrier 11. The carrier 10 has a first surface 10s1 facing the carrier 11 and a second surface 10s2 opposite to the first surface 10s1. In some embodiments, the carrier 10 may include an interposer. In some embodiments, the carrier 10 may include, for example, a printed circuit board (PCB), such as a paper-based copper foil laminate, a composite copper foil laminate, or a polymer-impregnated glass-fiber-based copper foil laminate. In some embodiments, the carrier 10 may include a semiconductor substrate including silicon, germanium, or other suitable materials. The carrier 10 may be referred to as a substrate or a circuit structure.

The carrier 10 may include a plurality of conductive elements 10c disposed at the second surface 10s2. The conductive elements 10c may include conductive pads for connecting an external system, device, etc. The carrier 10 may include a pad (or a conductive pad) 171 and a pad (or a conductive pad) 172 disposed at the first surface 10s1. The pad 171 and the pad 172 may be electrically connected to the component 13.

In some embodiments, the pad 171 and the pad 172 may be formed of metal or metal alloy. The pad 171 and the pad 172 may include metal, such as copper, gold, silver, aluminum, titanium, tantalum, or the like. In some embodiments, the pad 171 and the pad 172 may include an intermetallic compound (IMC).

The carrier 10 may include a passivation layer 101 disposed on the first surface 10s1 of the carrier 10. The passivation layer 101 may surround the pads 171 and 172. The passivation layer 101 may include a solder mask or solder resist. The passivation layer 101 may prevent the unwanted electrical connections between solder materials and the conductive layers embedded in the carrier 10.

The carrier 11 is disposed over the component 13. The carrier 11 is disposed above the carrier 10. The carrier 11 has a first surface 11s1 facing the carrier 11 and a second surface 11s2 opposite to the first surface 11s1. In some embodiments, the carrier 11 may include an interposer. In some embodiments, the carrier 11 may include, for example, a printed circuit board (PCB), such as a paper-based copper foil laminate, a composite copper foil laminate, or a polymer-impregnated glass-fiber-based copper foil laminate. In some embodiments, the carrier 11 may include a semiconductor substrate including silicon, germanium, or other suitable materials. The carrier 11 may be referred to as a substrate or a circuit structure.

The carrier 11 may include a plurality of conductive elements 11c disposed at the second surface 11s2. The conductive elements 11c may include conductive pads for connecting an external system, device, etc. The carrier 11 may include a pad (or a conductive pad) 161 and a pad (or a conductive pad) 162 disposed at the first surface 11s1. The pad 161 and the pad 162 may be electrically connected to the component 13.

The carrier 11 may include a passivation layer 111 disposed on the first surface 11s1 of the carrier 11. The passivation layer 111 may surround the pads 161 and 162. The passivation layer 111 may include a solder mask or solder resist. The passivation layer 111 may prevent the unwanted electrical connections between solder materials with the conductive layers embedded in the carrier 11.

In some embodiments, the pad 161 and the pad 162 may be formed of metal or metal alloy. The pad 161 and the pad 162 may include metal, such as copper, gold, silver, aluminum, titanium, tantalum, or the like. In some embodiments, the pad 161 and the pad 162 may include an intermetallic compound (IMC).

The encapsulating layer 12 may be disposed between the carrier 10 and the carrier 11. The encapsulating layer 12 may encapsulate the component 13. The encapsulating layer 12 may be disposed on the lateral surfaces of the carrier 11. The second surface 11s2 of the carrier 11 may be exposed by the encapsulating layer 12. The encapsulating layer 12 may have a lateral surface substantially coplanar with a lateral surface of the carrier 10.

In some embodiments, the encapsulating layer 12 may include an epoxy resin including fillers, a molding compound (e.g., an epoxy molding compound or other molding compound), polyimide, a phenolic compound or material, a material including silicone dispersed therein, or a combination thereof.

The component 13 may have a first surface 13s1 facing the carrier 10 and a second surface 13s2 facing the carrier 11. The component 13 may be disposed between the carrier 10 and the carrier 11. The component 13 may connect the carrier 10 to the carrier 11. The component 13 may be configured to support the carrier 11. The component 13 may include a surface mount device (SMD). The component 13 may include a passive component, such as a resistor, inductor, a capacitor, or an active component, such as an amplifier. The component 13 is configured to filter noise from the signals transmitted between the carrier 10 and the carrier 11. The component 13 may include a decoupling capacitor. The component 13 may include a capacitor, a ceramic capacitor, a deep trench capacitor (DTC), or the like.

The package structure 100 may further include a plurality of components disposed between the carrier 10 and the carrier 11. The components may be disposed adjacent to the component 13. The components may connect the carrier 10 to the carrier 11. The components may be electrically connected to the component 13 in series or in parallel through the carrier 10 or the carrier 11. In some embodiments, the components may be configured to support the carrier 11. The components can be indicated with the numeral 13 for brevity.

The component 13 may include a first terminal 14 and a second terminal 15. The first terminal 14 is spaced apart from the second terminal 15 to prevent a short-circuit. The first terminal 14 may be electrically connected to the pad 161 of the carrier 11 and/or the pad 171 of the carrier 10. The second terminal 15 may be electrically connected to the pad 162 of the carrier 11 and/or the pad 172 of the carrier 10. The pad 171 and the pad 172 respectively overlap the first terminal 14 and the second terminal 15 in a direction perpendicular to the first surface 10s1 of the carrier 10. The pad 161 and the pad 162 respectively overlap the first terminal 14 and the second terminal 15 in a direction perpendicular to the first surface 11s1 of the carrier 11.

The package structure 100 further includes a connection element 18 and a connection element 19. The connection element 18 is spaced apart from the connection element 19. The connection element 18 may connect the carrier 10 to the carrier 11. The connection element 19 may connect the carrier 10 to the carrier 11. The connection element 18 may be in contact with the first terminal 14, the pad 161, and the pad 171. The connection element 18 may surround the first terminal 14. The connection element 18 connects the first terminal 14 to the pad 161 of the carrier 11 and the pad 171 of the carrier 10. The connection element 19 may be in contact with the second terminal 15, the pad 162, and the pad 172. The connection element 19 may surround the second terminal 15. The connection element 18 connects the second terminal 15 to the pad 162 of the carrier 11 and the pad 172 of the carrier 10.

In some embodiments, the connection element 18 and the connection element 19 may include a solder paste, solder balls, controlled collapse chip connection (C4) bumps, a ball grid array (BGA), or a land grid array (LGA).

The pads 171 and 161 are located more outward than the first terminal 14 with respect to a central line 13c of the component 13. The pads 172 and 162 are located more outward than the second terminal 15 with respect to the central line 13c of the component 13. The central line 13c may be perpendicular to the first surface 10s1 of the carrier 10. A distance D23 between the pad 171 and the pad 172 is greater than a distance D10 between the first terminal 14 and the second terminal 15. The distance D23 is defined by the inner sidewalls of the pad 171 and the pad 172. The distance D10 is defined by the inner sidewalls of the first terminal 14 and the second terminal 15. distance D33 between the pad 161 and the pad 162 is greater than the distance D10. The distance D33 is defined by the inner sidewalls of the pad 161 and the pad 162. The profile of the encapsulating layer 12 between the component 13 and the pads 171 and 172 (or the pads 161 and 162) can be shaped to reduce the localized stress at the boundary between the encapsulating layer 12 and the component 13 ((or between the encapsulating layer 12 and the connection elements 18, 19). The details will be discussed in the following content.

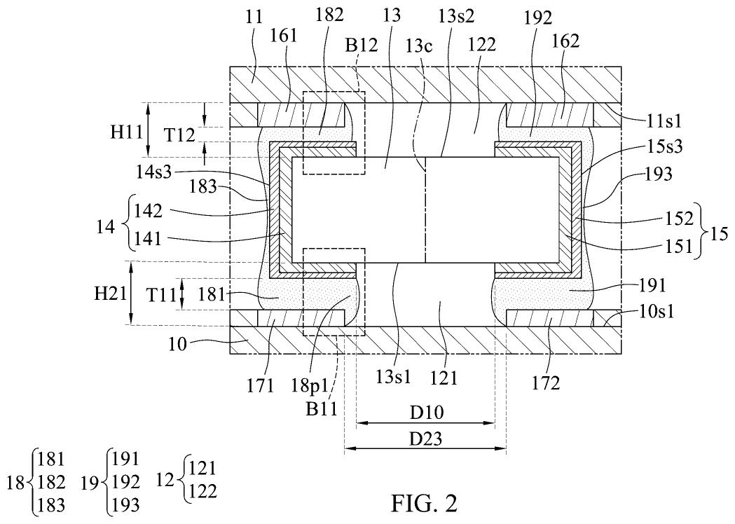

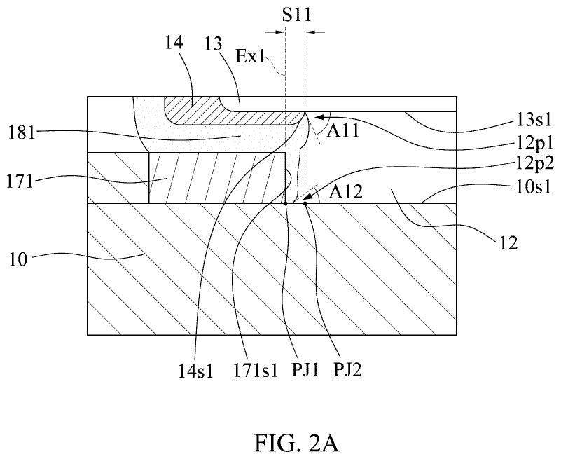

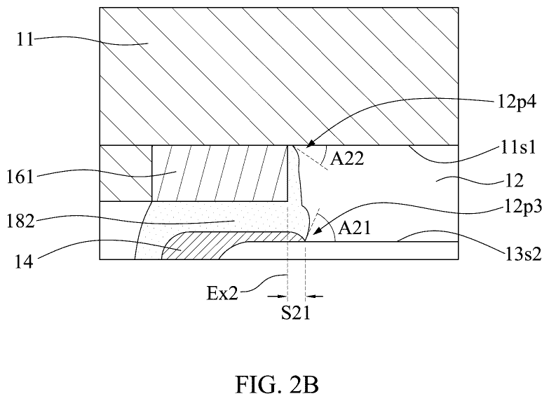

FIG. 2 is an enlarged cross-sectional view of a box B1 in FIG. 1. As shown in FIG. 2, an inner portion of the terminal 14 is free from overlapping the pad 171 in a direction perpendicular to the first surface 10s1 of the carrier 10. An inner portion of the terminal 14 is free from overlapping the pad 161 in a direction perpendicular to the first surface 11s1 of the carrier 11. An inner portion of the terminal 15 is free from overlapping the pad 172 in a direction perpendicular to the first surface 10s1 of the carrier 10. An inner portion of the terminal 15 is free from overlapping the pad 162 in a direction perpendicular to the first surface 11s1 of the carrier 11.

In some cases, a package structure may include a component for connecting an upper substrate to a lower substrate via a solder material. The component is encapsulated by a molding compound. In a cross-sectional view, a portion of the molding compound directly under or above the component may have a trapezoid shape having a longer side closer to the component and a shorter side closer to the upper substrate/lower substrate. The sharper corners at the longer side of the trapezoid shape may induce relatively strong localized stress at the corners.

In the present disclosure, due to the distance D23 being greater than the distance D10, a portion 121 of the encapsulating layer 12 directly under the component 13 may have a substantially rectangular profile. The angles of the substantially rectangular portion 121 of the encapsulating layer 12 may be larger than 45 degrees. Due to the distance D33 being greater than the distance D10, a portion 122 of the encapsulating layer 12 directly above the component 13 may have a substantially rectangular profile. The angles of the substantially rectangular portion 122 of the encapsulating layer 12 may be larger than 45 degrees. The localized stress at the corner of the substantially rectangular portions 121 and 122 may be relatively small. The risk of delamination can be reduced.

In some embodiments, the portion 121 and the portion 122 of the encapsulating layer 12 may have a substantially trapezoid shape having a longer side closer to the carrier 10/carrier 11 and a shorter side closer to the component 13.

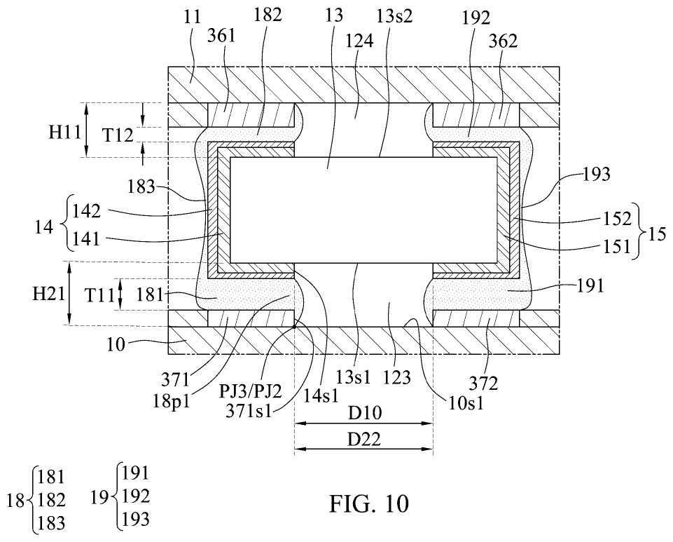

FIG. 2A is an enlarged cross-sectional view of a box B11 in FIG. 2. As shown in FIG. 2A, an inner sidewall 14s1 of the terminal 14 may be misaligned with an inner sidewall 171s1 of the pad 171. The terminal 14 as shown in FIG. 2A may be one layer. In some embodiments, the terminal 14 may include multiple layers as shown in FIG. 2. The inner sidewall 14s1 may be curved. In some embodiments, the inner sidewall 14s1 may be substantially vertical to the surface 13s1 of the component 13 (as shown in FIG. 2). A projection of the inner sidewall 14s1 on the first surface 13s1 of the component 13 is spaced apart from a projection of the inner sidewall 171s1 on the first surface 13s1 by a distance S11. An imaginary extension line Ex1 of the inner sidewall 171s1 of the pad 171 may penetrate through the terminal 14. A projection PJ1 of the inner sidewall 171s1 on the first surface 10s1 may be close to a projection PJ2 of the inner sidewall 14s1 on the first surface 10s1 to reduce the stress between the connection element 18 and the encapsulating layer 12. The projection PJ1 may be spaced apart from the projection PJ2 with the distance S11. In some embodiments, the inner sidewall 14s1 may be substantially aligned with the inner sidewall 371s1 of the pad 371 (see FIG. 10).

The connection element 18 may have a portion 181 between the component 13 and the carrier 10. The portion 181 may have a lateral surface 181s1 with a double-convex shape. The double-convex shape may have a first convex portion adjacent to the pad 171 and a second convex portion adjacent to the first terminal 14. A first acute angle A11 defined by the portion 181 and the component 13 is greater than a second acute angle A12 defined by the portion 181 and the carrier 10. The first acute angle A11 may be defined by the lateral surface 181s1 of the portion 181 and the first surface 13s1 of the component 13. The first acute angle A11 may be greater than 45 degrees. The second acute angle A12 may be defined by the lateral surface 181s1 of the portion 181 and the first surface 10s1 of the carrier 10. The encapsulating layer 12 may include a first protrusion 12p1 at a first corner defined by the connection element 18 and the component 13, and a second protrusion 12p2 at a second corner defined by the connection element 18 and the carrier 10. A first volume of the first protrusion 12p1 is smaller than a second volume of the second protrusion 12p2.

In some cases, a package structure may include a component for connecting an upper substrate to a lower substrate via a solder material. The component is encapsulated by a molding compound. A distance between the pads for connecting to the same component is smaller than that between the terminals of said component. Thus, an angle defined by the component and the solder material is relatively smaller than the other angle defined by the solder material and the upper/lower carrier. As such, the localized stress at the corner around the angle is strong enough to cause a delamination (or a crack) between the component and the molding compound. In the present disclosure, the acute angle A11 is greater than the acute angle A12, such that the localized stress around the corner of the acute angle A11 can be reduced. The risk of delamination between the encapsulating layer 12 and the component 13 can be reduced or eliminated.

FIG. 2B is an enlarged cross-sectional view of a box B11 in FIG. 2. As shown in FIG. 2A, the inner sidewall 14s1 of the terminal 14 may be misaligned with an inner sidewall 161s1 of the pad 161. A projection of the inner sidewall 14s1 on the second surface 13s2 of the component 13 is spaced apart from a projection of the inner sidewall 161s1 on the second surface 13s2 by a distance S21. An imaginary extension line Ex2 of the inner sidewall 161s1 of the pad 161 may penetrate through the terminal 14. In some embodiments, the inner sidewall 14s1 may be substantially aligned with the inner sidewall 361s1 of the pad 361 (see FIG. 10).

The connection element 18 may have a portion 182 between the component 13 and the carrier 11. The portion 182 may have a lateral surface 182s1 with a double-convex shape. The double-convex shape may have a first convex portion adjacent to the pad 161 and a second convex portion adjacent to the first terminal 14. A third acute angle A21 defined by the portion 182 and the component 13 is greater than a fourth acute angle A22 defined by the portion 182 and the carrier 11. The third acute angle A21 may be defined by the lateral surface 182s1 of the portion 182 and the second surface 13s2 of the component 13. The third acute angle A21 may be greater than 45 degrees. The fourth acute angle A22 may be defined by the lateral surface 182s1 of the portion 182 and the first surface 11s1 of the carrier 11. The encapsulating layer 12 may include a third protrusion 12p3 at a third corner defined by the connection element 18 and the component 13 and a fourth protrusion 12p4 at a fourth corner defined by the connection element 18 and the carrier 11. A third volume of the third protrusion 12p3 is smaller than a fourth volume of the fourth protrusion 12p4.

The acute angle A21 is greater than the acute angle A22, such that the localized stress around the corner of the acute angle A21 can be reduced. The risk of delamination between the encapsulating layer 12 and the component 13 can be reduced or eliminated.

In some embodiments, the location of the pad 172 may be symmetrical to that of the pad 171 with respect to the imaginary central line of the component 13. The structure and features as shown in FIG. 2A may also be applied to the region around the pad 172. In some embodiments, the connection element 19 may include a portion 191 having a double-convex lateral surface. An acute angle defined by the portion 191 and the component 13 is greater than an acute angle defined by the portion 191 and the carrier 10.

In some embodiments, the location of the pad 162 may be symmetrical to that of the pad 161 with respect to the imaginary central line of the component 13. The structure as shown in FIG. 2B may also be applied to the region around the pad 162. In some embodiments, the connection element 19 may include a portion 192 having a double-convex lateral surface. An acute angle defined by the portion 192 and the component 13 is greater than an acute angle defined by the portion 192 and the carrier 11.

Referring back to FIG. 2, the connection element 18 may include a portion 183 disposed along a lateral surface 14s3 of the first terminal 14. The portion 183 may be connected to the portion 181 and the portion 182. The connection element 18 may have a necking profile. The portion 183 may be narrower than the portion 181 and the portion 182 in a direction substantially perpendicular to the first surface 10s1 of the carrier 10. The portion 183 may have a necking profile. The thickness of the portion 183 may decrease from the top side to the middle side and from the bottom side to the middle side. The connection element 18 at the lateral surface 14s3 of the first terminal 14 of the component 13 may have the smallest width. In some embodiments, the components 13 are densely arranged (i.e., the spacing therebetween is relatively small), the necking profile of the connection element 18 with a shorter width at its middle side can prevent bridges between the connection element 18 and other adjacent connection elements.

In some embodiments, the connection element 19 may include a portion 193 disposed along a lateral surface 15s3 of the second terminal 15. The portion 193 may be connected to the portion 191 and the portion 192. The connection element 19 may have a necking profile. The portion 193 may be narrower than the portion 191 and the portion 192 in a direction substantially perpendicular to the first surface 11s1 of the carrier 11. The portion 193 may have a necking profile. The thickness of the portion 193 may decrease from the top side to the middle side and from the bottom side to the middle side. The connection element 19 at the lateral surface 15s3 of the second terminal 15 may have the smallest width. In some embodiments, the components 13 are densely arranged (i.e., the spacing therebetween is relatively small), the necking profile of the connection element 19 with a shorter width at its middle side can prevent bridges between the connection element 19 and other adjacent connection elements.

The component 13 (and the other components) are mounted to the carrier 11 prior to being mounted to the carrier 10. The carrier 11 with the one or more components may exhibit warpage (e.g., a smiling profile). In order to connect each of the components to the pads (including the pads 171 and 172), the amount of the solder material is relatively large (compared to those for the carrier 11) to compensate for the warpage of the carrier 11. Thus, after thermal treatment, the amount of the solders between the component 13 (and the other components) and the carrier 10 is greater than that between the component 13 and the carrier 11. As shown in FIG. 2, a thickness T11 of the portion 181 of the connection element 18 may be greater than a thickness T12 of the portion 183. The component 13 (and the other components) are closer to the carrier 11 than to the carrier 10. As shown in FIG. 2, a distance H21 between the first surface 13s1 of the component 13 and the carrier 10 (or the first surface 10s1) may be greater than a distance H11 between the second surface 13s2 and the carrier 11 (or the first surface 11s1).

In some embodiments, the component 13 may be a ceramic capacitor. The first terminal 14 may include a portion 141 and a portion 142. The portion 142 may surround the portion 141. The portion 141 and the portion 142 may be formed by different materials. In some embodiments, the portion 141 may be made of Sn, while the portion 142 may be made of Cu. The second terminal 15 may include a portion 151 and a portion 152. The portion 152 may surround the portion 151. The portion 151 and the portion 152 may be formed by different materials. In some embodiments, the portion 151 may be made of Sn, while the portion 152 may be made of Cu. The connection element 18 may be joined with the first terminal 14. The connection element 18 may not be joined with the first surface 13s1 and the second surface 13s2 of the component 13. The connection element 19 may be joined with the second terminal 15. The connection element 19 may not be joined with the first surface 13s1 and the second surface 13s2 of the component 13.

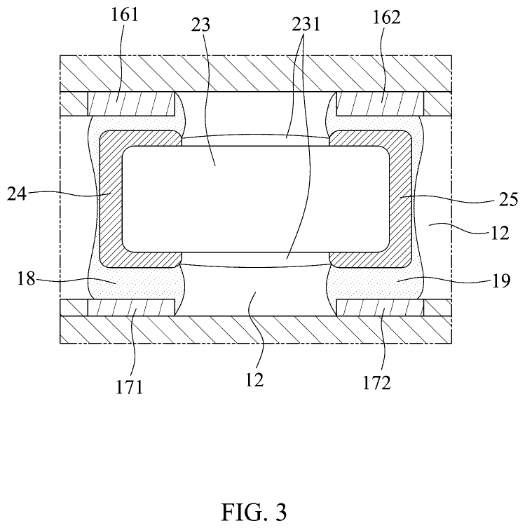

FIG. 3 is another enlarged cross-sectional view of a box B1 in FIG. 1. The structure in FIG. 3 is similar to that in FIG. 2. Therefore, some detailed descriptions may refer to corresponding preceding paragraphs and are not repeated hereinafter for conciseness, with differences therebetween as follows.

As shown in FIG. 3, the component 13 is replaced by a resistor 23. The resistor 23 may include an insulating layer 231 covering the upper and lower surfaces of the resistor 23. The resistor 23 may include a first terminal 24 connecting to the pad 161 and the pad 171. The connection element 18 may be joined with the first terminal 24. The connection element 18 may not be joined with the insulating layer 231. The resistor 23 may include a second terminal 25 connecting to the pad 162 and the pad 172. The connection element 19 may be joined with the second terminal 25. The connection element 19 may not be joined with the insulating layer 231.

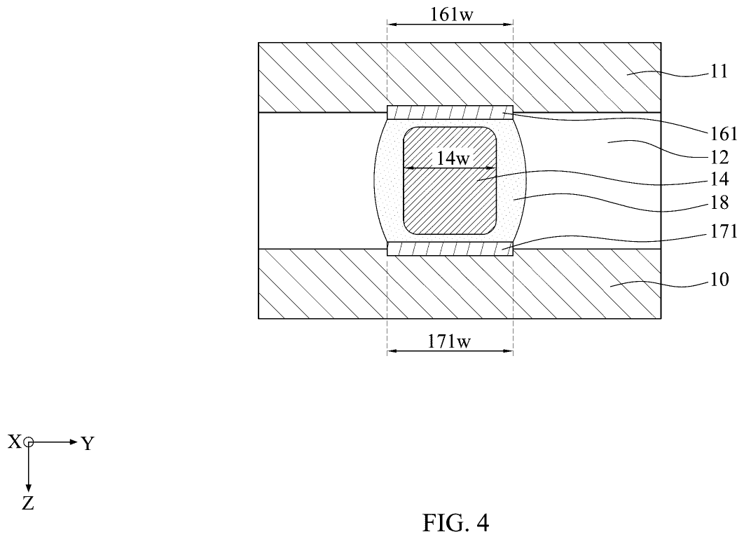

FIG. 4 is an enlarged cross-sectional view of a box B1 in FIG. 1 in a viewing direction perpendicular to the viewing direction of FIG. 2. As shown in FIG. 4, in the Y direction, the pad 161 has a width 161w, the pad 171 has a width 171w, and the terminal 14 has a width 14w. The width 161w may be larger than the width 14w. The width 171w may be larger than the width 14w. As shown in FIG. 4, the pad 161 and the pad 171 may completely overlap the terminal 14 in a direction perpendicular to the first surface 10s1 of the carrier 10. This may improve the connection between the terminal 14 and the pad 161 (and the pad 171).

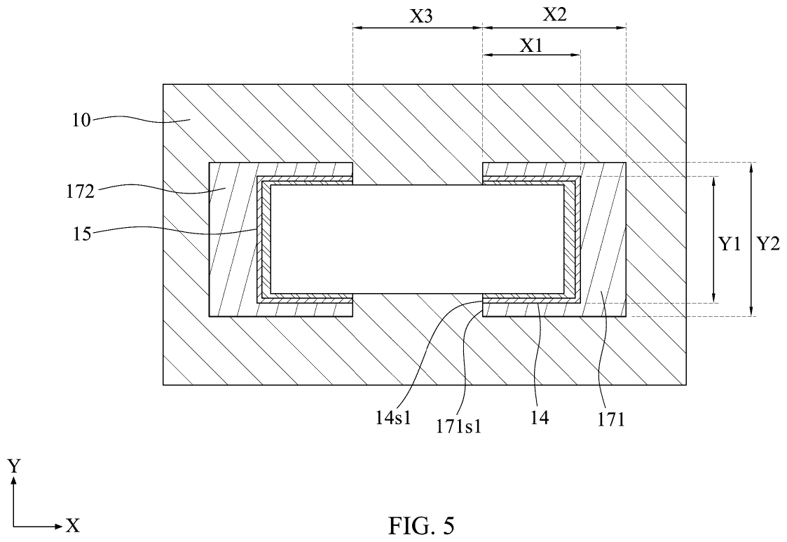

FIG. 5 is an enlarged top view of a box B1 in FIG. 1. The coverage of the terminal 14 to the pad 171 may be smaller or equal to about 70%, 60%, 50%, 40%, 30%, or less. The terminal 14 may have a dimension X1 in the X direction and a dimension Y1 in the Y direction. The dimension X1 may be around 150 μm˜200 μm. The dimension Y1 may be around 300 μm˜350 μm. The pad 171 may have a dimension X2 in the X direction and a dimension Y2 in the Y direction. The dimension X2 may be around 200 μm˜250 μm. The dimension X2 may be greater than the dimension X1. The dimension Y2 may be around 350 μm˜450 μm. The dimension Y2 may be greater than the dimension Y1. FIG. 5 shows that the inner sidewall 14s1 of the terminal 14 is substantially aligned with the inner sidewall 171s1 of the pad 171. In the X direction, a distance X3 between the terminal 14 and the terminal 15 may be around 250 μm˜350 μm. The distance X3 may be greater than the dimension X1 and the dimension X2.

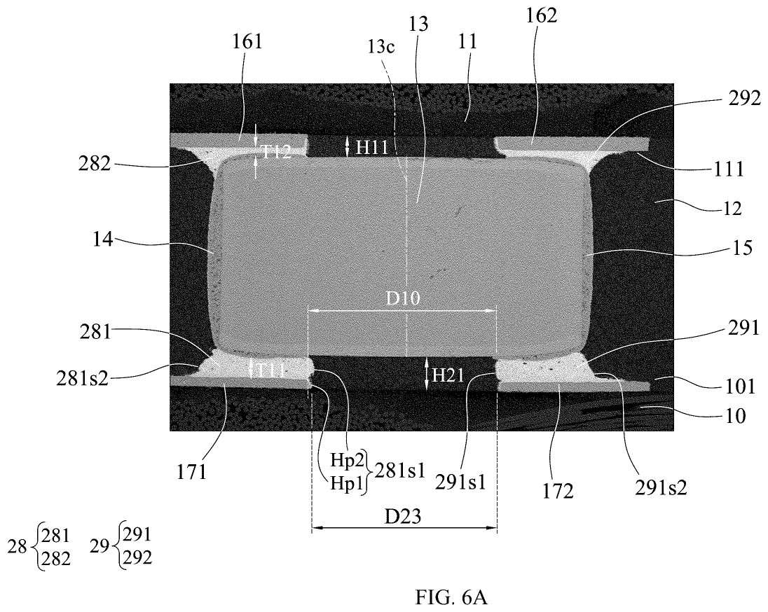

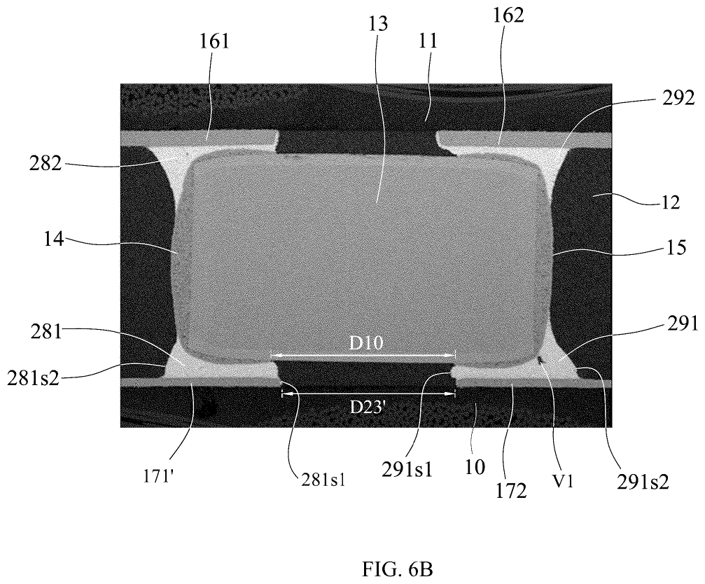

FIG. 6A is a Scanning Electron Microscope (SEM) image of a portion of a package structure (e.g., the package structure 100) according to some embodiments of the present disclosure. The component 13 in FIG. 6A may be located at the edge part of the package structure 100.

FIG. 6A shows that a connection element 28 includes a first portion 281 connecting the terminal 14 to the pad 171 and a second portion 282 connecting the terminal 14 to the pad 161. The first portion 281 is spaced apart from the second portion 282. The first portion 281 may be at a level between the pad 171 and the first terminal 14, and protruding from both the first terminal 14 and the pad 171.

FIG. 6A also shows that a connection element 29 includes a first portion 291 connecting the terminal 15 to the pad 172 and a second portion 292 connecting the terminal 15 to the pad 162. The first portion 291 is spaced apart from the second portion 292. The first portion 291 may be at a level between the pad 172 and the second terminal 15, and protruding from both the second terminal 15 and the pad 172.

The portion 281 may have a lateral surface 281s1 directly below the component 13 and a lateral surface 281s2 opposite to the lateral surface 281s1. The lateral surface 281s1 may be steeper than the lateral surface 281s2 with respect to the first terminal 14. The lateral surface 281s1 may be substantially convex. The lateral surface 281s1 may be more convex than the lateral surface 281s2. The lateral surface 281s1 of the first portion 281 of the connection element 28 may have a double-convex shape. The double-convex shape has a first convex portion Hp1 adjacent to the pad 171 and a second convex portion Hp2 between the first convex portion Hp1 and the first terminal 14. The second convex portion Hp2 is larger than the first convex portion Hp1. Similarly, the portion 291 may have a lateral surface 291s1 directly below the component 13 and a lateral surface 291s2 opposite to the lateral surface 291s1. The lateral surface 291s1 may be steeper than the lateral surface 291s2 with respect to the second terminal 15. The lateral surface 291s1 may be substantially convex. The lateral surface 291s1 may be more convex than the lateral surface 291s2. The lateral surface 291s1 has a double-convex shape. The lateral surface 291s1 may face the lateral surface 281s1.

The SEM image of FIG. 6A may show the location variations of the pads 161, 162, 171, and 172. The location variations may come from the process variations. In some embodiments, the pads 161, 171, and 172 are located more outward than the corresponding terminal with respect to the central line 13c of the component 13. The pad 162 is located more inward than the corresponding terminal with respect to the central line 13c of the component 13. As shown in FIG. 6A, the acute angle defined by the component 13 and the terminal 15 at the region around the pad 162 is smaller than the other acute angles at the other regions around the pads 161, 171, and 172. The protrusion of the encapsulating layer 12 at the region around the pad 162 is larger than the other protrusion of the encapsulating layer at the other regions. The region around the pad 162 may have a higher risk of delamination than the other regions around the pads 161, 171, and 172.

In some embodiments, a portion of the encapsulating layer 12 directly under the component 13 may have a substantially rectangular profile. The localized stress at the corner of the substantially rectangular portion may be relatively small. The risk of delamination can be reduced.

FIG. 6B is an SEM image of a portion of a package structure (e.g., the package structure 100) according to some embodiments of the present disclosure. The component 13 in FIG. 6B may be located at the central part of the package structure 100. The SEM image of FIG. 6B may be similar to that of FIG. 6A. Therefore, some detailed descriptions may refer to corresponding preceding paragraphs and are not repeated hereinafter for conciseness, with differences therebetween as follows.

The pad 171 may be located more inward than the terminal 14. A distance D23′ of FIG. 6B may be shorter than the distance D23 of FIG. 6A. Furthermore, a void V1 may be located at the first portion 291 of the connection element 29. The void V1 may be located adjacent to the boundary between the terminal 15 and the first portion 291 of the connection element 29. The void V1 may be a crack in the connection element 29.

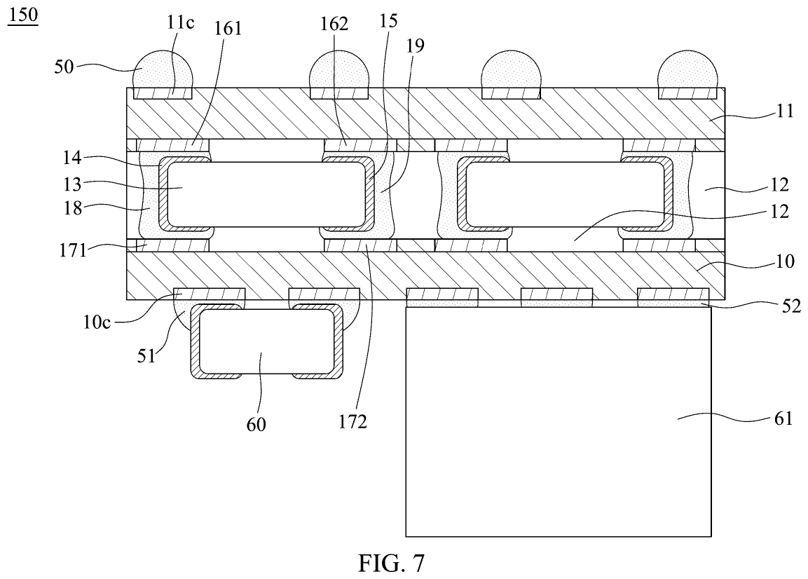

FIG. 7 is a cross-sectional view of a package structure 150 according to some embodiments of the present disclosure. The package structure 150 in FIG. 7 is similar to the package structure 100 in FIG. 1. Therefore, some detailed descriptions may refer to corresponding preceding paragraphs and are not repeated hereinafter for conciseness, with differences therebetween as follows.

As shown in FIG. 7, the conductive elements 11c of the carrier 11 may be connected with a plurality of conductive contacts 50. A first group and a second group of the conductive elements 10c of the carrier 10 may be respectively connected with a plurality of conductive contacts 51 and a plurality of conductive contacts 52.

The package structure 150 may further include a component 60 mounted to the conductive elements 10c of the carrier 10 through the conductive contacts 51. The component 60 may include a passive component. The package structure 150 may further include a power module 61 mounted to the conductive elements 10c of the carrier 10 through the conductive contacts 52. The power module 61 may be configured to supply power to the component 13 and the component 60. The power module 61 may be configured to supply power to an external device or system through the carrier 10, the component 13, and the carrier 11.

In some embodiments, the conductive contacts 50, 51, and 52 may include a solder paste, solder balls, controlled collapse chip connection (C4) bumps, a ball grid array (BGA), or a land grid array (LGA).

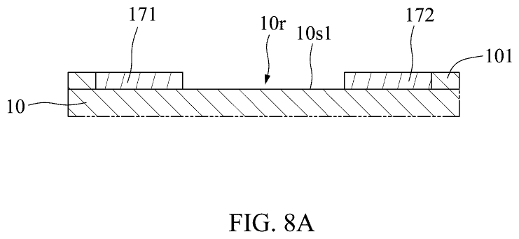

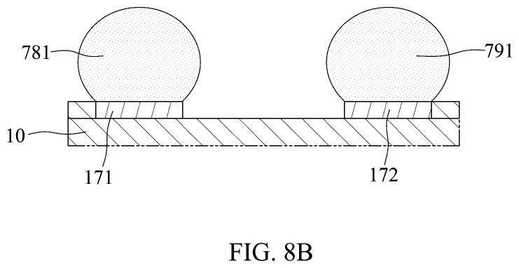

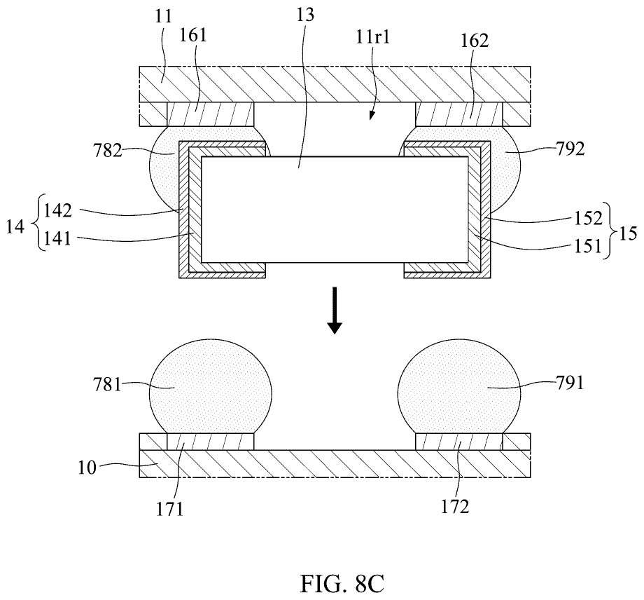

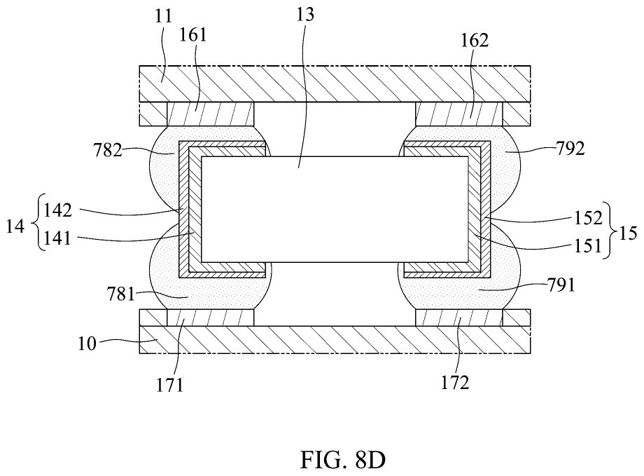

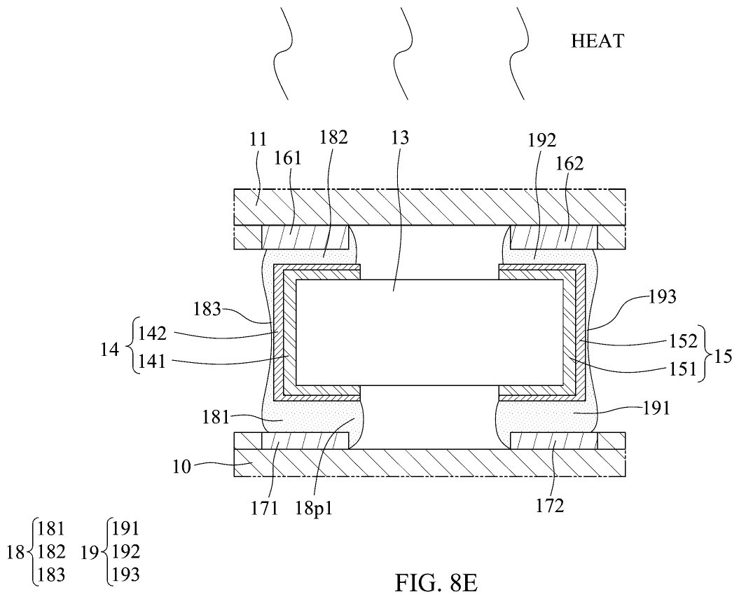

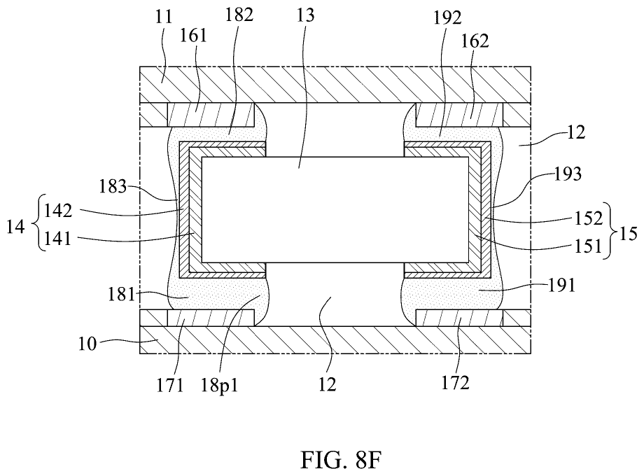

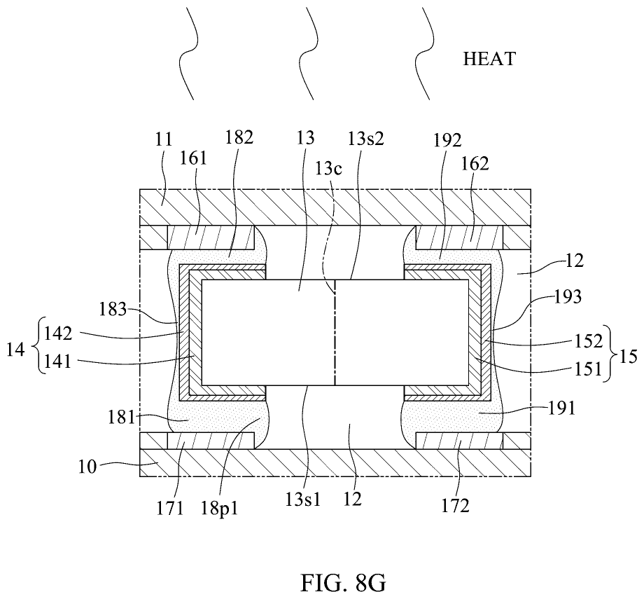

FIGS. 8A, 8B, 8C, 8D, 8E, 8F, and 8G illustrate one or more stages of an example of a method for manufacturing a package structure according to some embodiments of the present disclosure.

As shown in FIG. 8A, a carrier 10 with a plurality of pads 171 and 172 may be provided. A passivation layer 101 may be formed over the carrier 10. The pads 171 and 172 may be formed over a first surface 10s1 of the carrier 10 and surrounded by the passivation layer 101. FIG. 8A may show a portion of the carrier 10 for brevity. The pads 171 and 172 may define a recess 10r over the first surface 10s1 of the carrier 10. A portion of the first surface 10s1 may be exposed by the recess 10r.

As shown in FIG. 8B, a solder material 781 and a solder material 791 may be respectively formed on the pad 171 and the pad 172. The solder material 781 and the solder material 791 may have a round shape.

As shown in FIG. 8C, a carrier 11 with a plurality of pads 161 and 162 may be provided. A passivation layer 111 may be formed over the carrier 11. The pads 161 and 162 may be formed over a first surface 11s1 of the carrier 11 and surrounded by the passivation layer 111. FIG. 8C may show a portion of the carrier 11 for brevity. The pads 161 and 162 may define a recess 11r over the first surface 11s1 of the carrier 11. A portion of the first surface 11s1 may be exposed by the recess 11r. A solder material 782 and a solder material 792 may be respectively formed on the pad 161 and the pad 162. The solder material 782 and the solder material 792 may have a round shape.

A component 13 may be mounted to the carrier 11 via the solder material 782 and the solder material 792. The component 13 may have a first terminal 14 and a second terminal 15 spaced apart from the first terminal 14. The first terminal 14 may include a portion 141 and a portion 142. The portion 142 may surround the portion 141. The portion 141 and the portion 142 may be formed by different materials. The second terminal 15 may include a portion 151 and a portion 152. The portion 152 may surround the portion 151. The portion 151 and the portion 152 may be formed by different materials.

As shown in FIG. 8D, the component 13 may be mounted to the carrier 10 via the solder material 781 and the solder material 791. The carrier 10 may be connected to the carrier 11 through the component 13. The carrier 11 may exhibit warpage (e.g., a smiling profile). In order to connect each of the components to the pads (including the pads 171 and 172), the amount of the solder material is relatively large (compared to those for the carrier 11) to compensate for the warpage of the carrier 11. Thus, the amount of the solder materials between the component 13 (and the other components) and the carrier 10 is greater than those between the component 13 and the carrier 11. The component 13 may be closer to the carrier 11 than to the carrier 10.

As shown in FIG. 8E, a thermal treatment may be performed. The solder material 781 and the solder material 782 may be reflowed to form a connection element 18. The connection element 18 may have a necking profile. The connection element 18 may have a portion 181 between the first terminal 14 and the pad 171 of the carrier 10, a portion 182 between the first terminal 14 and the pad 161 of the carrier 11, and a portion 183 along a lateral surface 14s3 of the first terminal 14. The portion 183 may be connected to the portion 181 and the portion 182. The solder material 791 and the solder material 792 may be reflowed to form a connection element 19. The connection element 19 may have a necking profile. The connection element 19 may have a portion 191 between the second terminal 15 and the pad 172 of the carrier 10, a portion 192 between the second terminal 15 and the pad 162 of the carrier 11, and a portion 193 along a lateral surface 15s3 of the second terminal 15. The portion 193 may be connected to the portion 191 and the portion 192.

As shown in FIG. 8F, an encapsulating layer 12 may be formed between the carrier 10 and the carrier 11. The encapsulating layer 12 may encapsulate the component 13, the connection element 18, and the connection element 19. In some embodiments, the encapsulating layer 12 may be formed by holding the carrier 10 and the carrier 11 with a molding chase and injecting encapsulating materials into the space in the molding chase.

As shown in FIG. 8G, a thermal treatment may be performed. The encapsulating layer 12 may be cured to form the package structure 100 of FIG. 1. The encapsulating layer 12, the component 13, and the connection element 18 may have different Young's moduli. A delamination may occur at the boundary therebetween. In the present disclosure, the pads 171 and 161 are located more outward than the first terminal 14 with respect to a central line 13c of the component 13. The pads 172 and 162 are located more outward than the second terminal 15 with respect to the central line 13c of the component 13. A portion 121 of the encapsulating layer 12 directly under the component 13 may have a substantially rectangular profile. The angles of the substantially rectangular portion 121 of the encapsulating layer 12 may be larger than 45 degrees. The localized stress at the corner of the substantially rectangular portion 121 may be relatively small. The risk of delamination can be reduced.

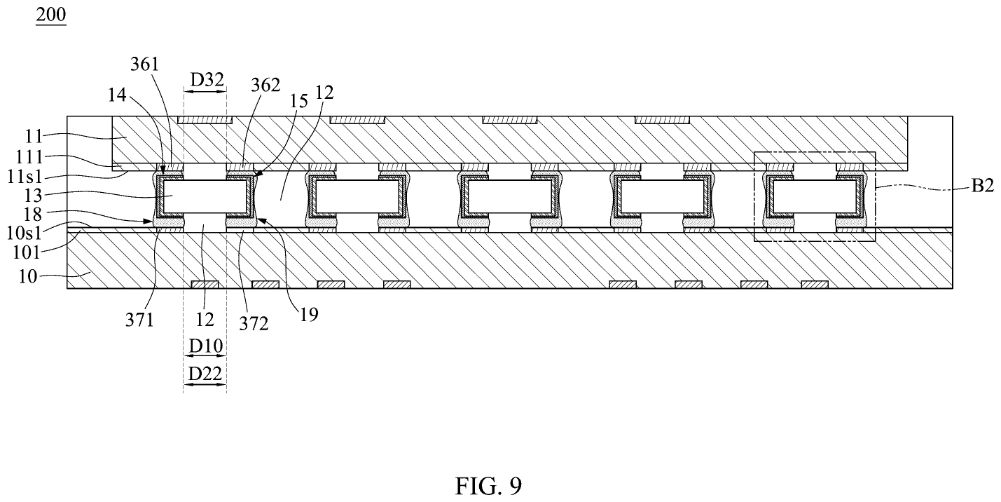

FIG. 9 is a cross-sectional view of a package structure according to some embodiments of the present disclosure. The package structure 200 in FIG. 9 is similar to the package structure 100 in FIG. 1. Therefore, some detailed descriptions may refer to corresponding preceding paragraphs and are not repeated hereinafter for conciseness, with differences therebetween as follows.

The carrier 10 of the package structure 200 may include a pad 371 and a pad 372 respectively connected to the first terminal 14 and the second terminal 15. The carrier 11 of the package structure 200 may include a pad 361 and a pad 362 respectively connected to the first terminal 14 and the second terminal 15. In some embodiments, a distance D22 between the pad 171 and the pad 172 is substantially equal to the distance D10 between the first terminal 14 and the second terminal 15. The distance D22 is defined by the inner sidewalls of the pad 371 and the pad 372. The distance D10 is defined by the inner sidewalls of the first terminal 14 and the second terminal 15. A distance D32 between the pad 361 and the pad 362 is substantially equal to the distance D10. The distance D32 is defined by the inner sidewalls of the pad 361 and the pad 362. The profile of the encapsulating layer 12 between the component 13 and the pads 371 and 372 (or the pads 361 and 362) can be shaped to reduce the localized stress at the boundary between the encapsulating layer 12 and the component 13.

FIG. 10 is an enlarged cross-sectional view of a box B2 in FIG. 9. Due to the distance D22 being substantially equal to the distance D10, a portion 123 of the encapsulating layer 12 directly under the component 13 may have a substantially rectangular profile. The angles of the substantially rectangular portion 123 of the encapsulating layer 12 may be larger than 45 degrees. Due to the distance D32 being substantially equal to the distance D10, a portion 124 of the encapsulating layer 12 directly above the component 13 may have a substantially rectangular profile. The angles of the substantially rectangular portion 124 of the encapsulating layer 12 may be larger than 45 degrees. The localized stress at the corner of the substantially rectangular portions 123 and 124 may be relatively small. The risk of delamination can be reduced.

In some embodiments, a projection PJ3 of the inner sidewall 371s1 on the first surface 10s1 may be close to the projection PJ2 of the inner sidewall 14s1 on the first surface 10s1 to reduce the stress between the connection element 18 and the encapsulating layer 12. The projection PJ3 may overlap the projection PJ2.

In some embodiments, the portion 123 and the portion 124 of the encapsulating layer 12 may have a substantially trapezoid shape having a longer side closer to the carrier 10/carrier 11 and a shorter side closer to the component 13.

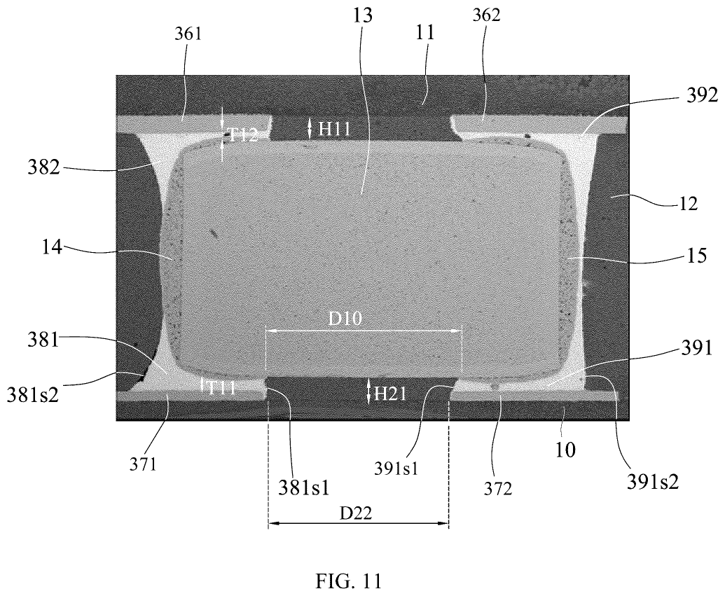

FIG. 11 is an SEM image of a portion of a package structure according to some embodiments of the present disclosure. FIG. 11 shows that a connection element 38 includes a first portion 381 connecting the first terminal 14 to the pad 371 and a second portion 382 connecting the first terminal 14 to the pad 361. The first portion 381 is spaced apart from the second portion 382. The first portion 381 may be at a level between the pad 371 and the first terminal 14, and protruding from both the first terminal 14 and the pad 371.

FIG. 11 also shows that a connection element 39 includes a first portion 391 connecting the second terminal 15 to the pad 372 and a second portion 392 connecting the second terminal 15 to the pad 362. The first portion 391 is spaced apart from the second portion 392. The first portion 391 may be at a level between the pad 372 and the second terminal 15, and protruding from both the second terminal 15 and the pad 372.

The portion 381 may have a lateral surface 381s1 directly below the component 13 and a lateral surface 381s2 opposite to the lateral surface 381s1. The lateral surface 381s1 may be steeper than the lateral surface 381s2 with respect to the first terminal 14. The lateral surface 381s1 may be substantially convex. The lateral surface 381s1 may be more convex than the lateral surface 381s2. The lateral surface 381s1 of the first portion 381 of the connection element 38 may have a double-convex shape. Similarly, the portion 391 may have a lateral surface 391s1 directly below the component 13 and a lateral surface 391s2 opposite to the lateral surface 391s1. The lateral surface 391s2 may be steeper than the lateral surface 391s1 with respect to the second terminal 15. The lateral surface 391s1 has a double-convex shape. The lateral surface 391s1 may face the lateral surface 381s1.

The SEM image of FIG. 11 may show the location variations of the pads 361, 362, 371, and 372. The location variations may come from the process variations. In some embodiments, the inner sidewalls of the pads 371 and 361 are aligned with the inner sidewall of the first terminal 14 with respect to the central line 13c of the component 13. The pads 362 and 372 are located more inward than the corresponding terminal with respect to the central line 13c of the component 13.

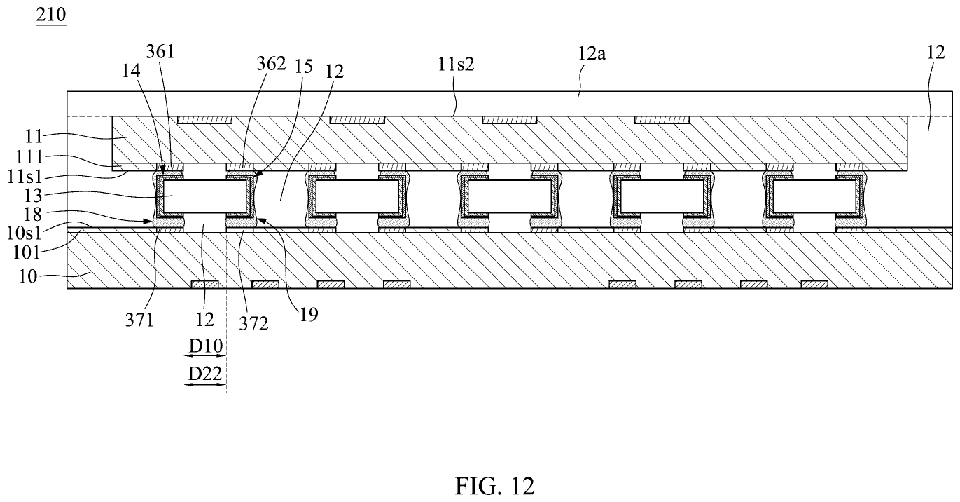

FIG. 12 is a cross-sectional view of an intermediate structure 210 during the manufacturing of a package structure according to some embodiments of the present disclosure. The intermediate structure 210 of FIG. 12 may be similar to the package structure 200 of FIG. 9, except that the encapsulating layer 12 of the intermediate structure 210 further includes a cap portion 12a covering the second surface 11s2 of the carrier 11. The cap portion 12a may be formed by separating the second surface 11s2 of the carrier 11 from the molding chase during the deposition of the encapsulating layer 12. The separation may reduce the pressure to the intermediate structure 210, and thus the risk of delamination between the component 13 and the encapsulating layer 12 can be reduced. After the formation of the encapsulating layer 12, the cap portion 12a may be removed to expose the second surface 11s2 of the carrier 11.

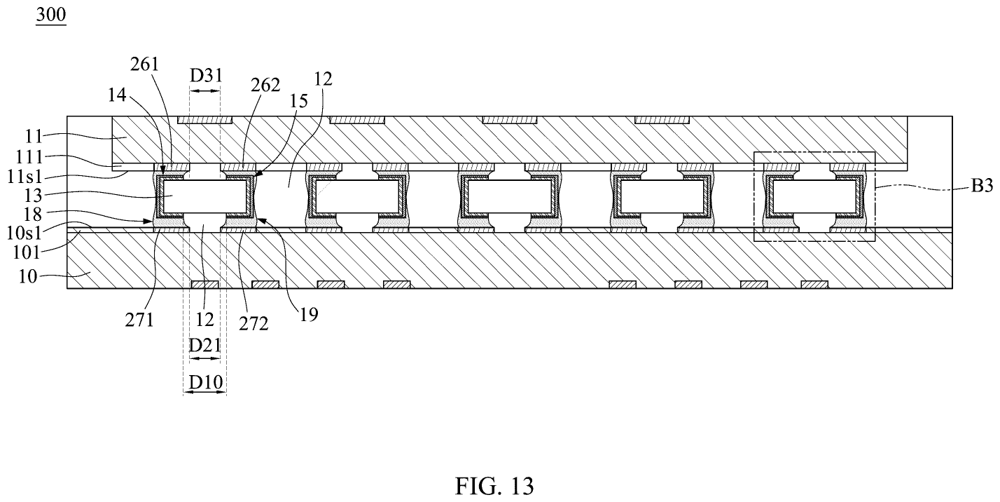

FIG. 13 is a cross-sectional view of a package structure 300 according to some embodiments of the present disclosure. The package structure 300 in FIG. 13 is similar to the package structure 100 in FIG. 1. Therefore, some detailed descriptions may refer to corresponding preceding paragraphs and are not repeated hereinafter for conciseness, with differences therebetween as follows.

The carrier 10 of the package structure 300 may include a pad 271 and a pad 272 respectively connected to the first terminal 14 and the second terminal 15. The carrier 11 of the package structure 200 may include a pad 261 and a pad 262 respectively connected to the first terminal 14 and the second terminal 15. In some embodiments, a distance D21 between the pad 171 and the pad 172 is smaller than the distance D10 between the first terminal 14 and the second terminal 15. The distance D21 is defined by the inner sidewalls of the pad 271 and the pad 272. The distance D10 is defined by the inner sidewalls of the first terminal 14 and the second terminal 15. distance D31 between the pad 261 and the pad 262 is smaller than the distance D10. The distance D31 is defined by the inner sidewalls of the pad 261 and the pad 262.

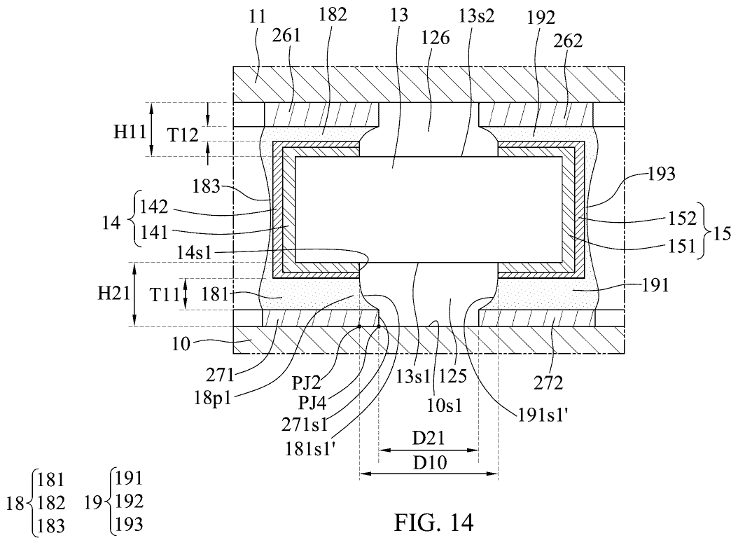

FIG. 14 is an enlarged cross-sectional view of a box B3 in FIG. 13. Due to the distance D21 being smaller than the distance D10, a portion 125 of the encapsulating layer 12 directly under the component 13 may have a trapezoid shape having a longer side closer to the component 13 and a shorter side closer to the carrier 10. Due to the distance D31 being smaller than the distance D10, a portion 126 of the encapsulating layer 12 directly above the component 13 may have a trapezoid shape having a longer side closer to the component 13 and a shorter side closer to the carrier 11.

The sharp corners at the longer side of the trapezoid shapes of the portions 125 and 126 may induce relatively strong localized stress at the corners (close to the component 13). The relatively strong localized stress may cause a delamination (or a crack) along the boundary between the encapsulating layer 12 and the component 13.

In some embodiments, the portion 181 of the connection element 18 may have a lateral surface 181s1′ directly under the component 13. The lateral surface 181s1′ may have a concave shape. The portion 191 of the connection element 19 may have a lateral surface 191s1′ directly under the component 13. The lateral surface 191s1′ may have a concave shape.

In some embodiments, the trapezoid shapes of the portions 125 and 126 may be adjusted by the design of the locations of the terminals 14 and 15, and the pads 261, 262, 271, and 272. In some embodiments, a projection PJ3 of the inner sidewall 271s1 on the first surface 10s1 may be close to the projection PJ2 of the inner sidewall 14s1 on the first surface 10s1 to reduce the stress between the connection element 18 and the encapsulating layer 12. As such, the lengths of the longer side can be close to the shorter side of trapezoid shape. The localized stress at the sharp corners of the longer side can be reduced.

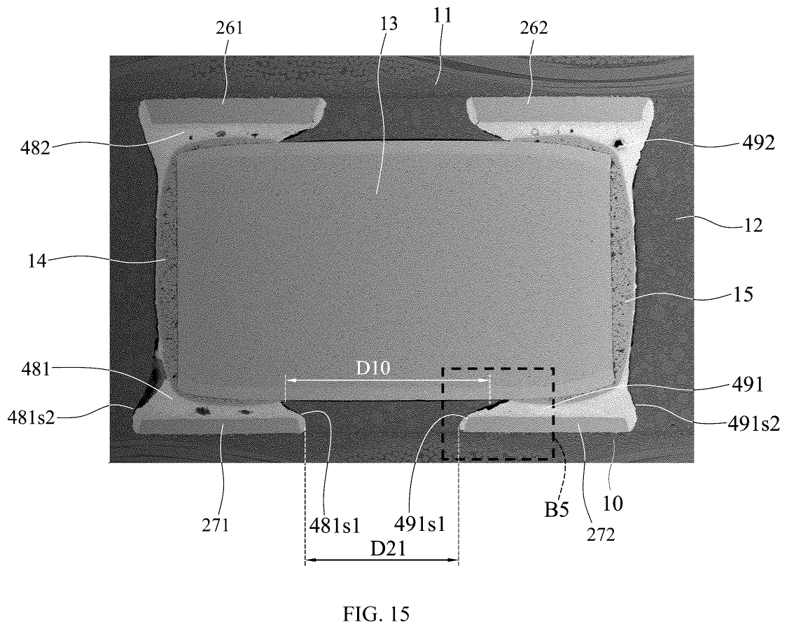

FIG. 15 is an SEM image of a portion of a package structure according to some embodiments of the present disclosure. FIG. 15 shows that a connection element 48 includes a first portion 481 connecting the first terminal 14 to the pad 271 and a second portion 482 connecting the first terminal 14 to the pad 261. The first portion 481 is spaced apart from the second portion 482. The first portion 481 may be at a level between the pad 271 and the first terminal 14, and recessed from the pad 271.

FIG. 15 also shows that a connection element 49 includes a first portion 491 connecting the second terminal 15 to the pad 272 and a second portion 492 connecting the second terminal 15 to the pad 262. The first portion 491 is spaced apart from the second portion 492. The first portion 491 may be at a level between the pad 272 and the second terminal 15, and recessed from the pad 272.

The portion 481 may have a lateral surface 481s1 directly below the component 13 and a lateral surface 481s2 opposite to the lateral surface 481s1. The lateral surface 481s2 may be steeper than the lateral surface 481s1 with respect to the first terminal 14. The lateral surface 481s1 of the first portion 481 of the connection element 48 may have a concave shape. The lateral surface 481s1 may be substantially concave and the lateral surface 481s2 may be substantially concave. The lateral surface 481s1 may be more concave than the lateral surface 481s2 . Similarly, the portion 491 may have a lateral surface 491s1 directly below the component 13 and a lateral surface 491s2 opposite to the lateral surface 491s1. The lateral surface 491s2 may be steeper than the lateral surface 491s1 with respect to the second terminal 15. The lateral surface 491s1 with a concave shape. The lateral surface 491s1 may face the lateral surface 481s1.

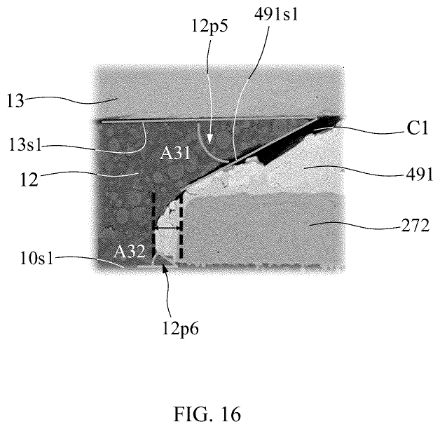

FIG. 16 is an enlarged cross-sectional view of a box B5 in FIG. 15. An acute angle A31 defined by the portion 491 and the component 13 is smaller than an acute angle A32 defined by the portion 491 and the carrier 10. The acute angle A31 may be defined by the lateral surface 491s1 of the portion 491 and the first surface 13s1 of the component 13. The acute angle A31 may be smaller than or substantially equal to around 30 degrees. The acute angle A32 may be defined by the lateral surface 491s1 of the portion 491 and the first surface 10s1 of the carrier 10. The encapsulating layer 12 may include a protrusion 12p5 at a corner defined by the portion 491 and the component 13 and a protrusion 12p6 at a corner defined by the portion 491 and the carrier 10. A volume of the protrusion 12p5 is larger than a volume of the protrusion 12p6.

As shown in FIG. 16, due to the acute angle A31 being relatively sharp, the localized stress at the corner of the acute angle A31 would cause a delamination between the component 13 and the encapsulating layer 12. A crack C1 may be located between the portion 491 of the connection element 49 and the encapsulating layer 12. The crack C1 does not include the encapsulating layer 12. The encapsulating layer 12 may not be disposed in the crack C1. The crack C1 may be a void. The void may be an empty space. The crack C1 may extend to the boundary between the portion 491 of the connection element 49 and the component 13. The crack C1 would impact the electrical connection between the component 13 and the pad 272 of the carrier 10. The reliability of the package structure 300 would be adversely impacted.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first carrier comprising a first pad and a second pad disposed at a first surface of the first carrier;
a second carrier disposed above the first carrier; and
a first component connecting the first carrier to the second carrier, and comprising a first terminal connected to the first pad and a second terminal connected to the second pad,
wherein a first distance between the first pad and the second pad is substantially equal to or greater than a second distance between the first terminal and the second terminal.

2. The package structure of claim 1, wherein the first pad and the second pad respectively overlap the first terminal and the second terminal in a direction perpendicular to the first surface of the first carrier.

3. The package structure of claim 1, further comprising a first connection element connecting the first carrier to the second carrier, wherein the first connection element is in contact with the first pad and the first terminal and has a necking profile.

4. The package structure of claim 3, wherein the first connection element comprises a first portion between the first component and the first carrier, wherein a first acute angle defined by the first portion and the first component is greater than a second acute angle defined by the first portion and the first carrier.

5. The package structure of claim 4, wherein the first acute angle is larger than 45 degrees.

6. The package structure of claim 4, wherein the first connection element further comprises a second portion disposed along a lateral surface of the first terminal and connecting to the first portion, wherein the second portion is narrower than the first portion in a direction substantially perpendicular to the first surface of the first carrier.

7. The package structure of claim 1, further comprising a first connection element disposed between the first pad and the first terminal and having a first lateral surface directly below the first component, wherein the first lateral surface is substantially convex.

8. The package structure of claim 3, further comprising an encapsulating layer disposed between the first carrier and the second carrier, wherein the encapsulating layer comprises a portion directly under the first component and having a substantially rectangular profile in a cross-sectional view.

9. A package structure, comprising:
a first carrier;
a second carrier disposed above the first carrier; and
a first component disposed between the first carrier and the second carrier,
wherein the first component has a first surface facing the first carrier and a second surface facing the second carrier, wherein a first distance between the first surface and the first carrier is greater than a second distance between the second surface and the second carrier.

10. The package structure of claim 9, wherein the first component is configured to support the second carrier.

11. The package structure of claim 9, further comprising a first connection element connecting the first carrier to the second carrier and comprising a first portion between the first component and the first carrier and a second portion between the first component and the second carrier, wherein a first thickness of the first portion is greater than a second thickness of the second portion.

12. The package structure of claim 11, wherein the first component comprises a first terminal surrounded by the first connection element, wherein the first connection element comprises a third portion disposed along a lateral surface of the first terminal and connected to the first portion and the second portion.

13. The package structure of claim 11, wherein the first portion is spaced apart from the second portion.

14. The package structure of claim 9, further comprising a plurality of components disposed between the first carrier and the second carrier, wherein the components and the first component are configured to support the second carrier.

15. The package structure of claim 9, further comprising a first connection element connecting the first component to the first carrier and an encapsulating layer disposed between the first component and the first carrier, wherein a crack is located between the first connection element and the encapsulating layer.

16. A package structure, comprising:
a first carrier comprising a first pad; and
a component disposed over the first carrier, and comprising a first terminal,
wherein, in a top view, a coverage of the first terminal to the first pad is smaller or equal to about 70%.

17. The package structure of claim 16, wherein, in a first direction, a first dimension of the first pad is greater than a second dimension of the first terminal, and, in a second direction substantially perpendicular to the first direction, a third dimension of the first pad is greater than a fourth dimension of the first terminal.

18. The package structure of claim 16, further comprising a first connection element connected to the first pad and the first terminal, wherein, in a cross-sectional view, the first connection element comprises a first portion at a level between the first pad and the first terminal, and protruding from the first terminal and the first pad.

19. The package structure of claim 16, wherein a first inner sidewall of the first pad is substantially aligned with a second inner sidewall of the first terminal.

20. The package structure of claim 19, wherein a first projection of the first inner sidewall on the first carrier overlaps a second projection of the second inner sidewall on the first carrier.
